(19) United States
(12) Patent Application Publication
(10) Pub. No.: US 2007/0145419 A1
(43) Pub. Date: Jun. 28, 2007

(54) Method of Manufacturing CMOS Image Sensor

(76) Inventor: In Seong Park, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/616,301

(22) Filed: Dec. 27, 2006

(30) Foreign Application Priority Data
Dec. 28, 2005 (KR) 10-2005-0132731

(51) Int. Cl. H01L 27/148

(52) U.S. Cl. 257/223

(57) ABSTRACT

A CMOS image sensor and a method of manufacturing the same are provided. The method is capable of reducing a distance between a micro-lens and a photodiode and simplifying the manufacturing process for the CMOS image sensor. In an embodiment, the interlayer dielectric layers of high level metal lines (e.g. third level and higher metal lines) can be selectively removed from the sensing section of a semiconductor substrate. The color filter layers and microlenses can be formed on the sensing section after the interlayer dielectric layers of the high level metal lines have been selectively removed.

### RELATED APPLICATION

This application claims the benefit under 35 U.S.C. §119(e), of Korean Patent Application Number 10-2005-0132731 filed Dec. 28, 2005, which is incorporated herein by reference in its entirety.

### FIELD OF THE INVENTION

The present invention relates to a method of manufacturing a complementary metal oxide semiconductor (CMOS) image sensor.

### BACKGROUND OF THE INVENTION

In general, an image sensor is a semiconductor device for converting optical images into electric signals, and is mainly classified as a charge coupled device (C CD) or a CMOS image sensor.

A CCD has a plurality of photodiodes (PDs), which are arranged in the form of a matrix in order to convert optical signals into electric signals. CCDs also include a plurality of vertical charge coupled devices (VCCDs) provided between photodiodes vertically arranged in the matrix. The VCCDs transmit electrical charges in the vertical direction when the electrical charges are generated from each photodiode. Additionally, CCDs have a plurality of horizontal charge coupled devices (HCCDs) for transmitting the electrical charges that have been transmitted from the VCCDs in the horizontal direction, and a sense amplifier for outputting electric signals by sensing the electrical charges being transmitted in the horizontal direction.

However, a CCD image sensor has various disadvantages, such as a complicated drive mode and high power consumption. Also, the CCD requires multi-step photo processes, so the manufacturing process is complicated.

In addition, it is difficult to integrate a controller, a signal processor, and an analog/digital converter (A/D converter) onto a single chip of the CCD. This leads to the CCD being not suitable for compact-size products.

Recently, the CMOS image sensor has been spotlighted as a next-generation image sensor capable of solving the problems of the CCD.

The CMOS image sensor is a device employing a switching mode to sequentially detect an output of each unit pixel by means of MOS transistors using peripheral devices, such as a controller and a signal processor. The MOS transistors are formed on a semiconductor substrate corresponding to the unit pixels through a CMOS technology.

That is, the CMOS image sensor includes a photodiode and a MOS transistor in each unit pixel, and sequentially detects the electric signals of each unit pixel in a switching mode to realize images.

Since the CMOS image sensor makes use of the CMOS technology, the CMOS image sensor has advantages such as the low power consumption and a simple manufacturing process with relatively fewer photo processing steps.

In addition, the CMOS image sensor allows the product to have a compact size, because the controller, the signal processor, and the A/D converter can be integrated onto a single chip. Therefore, CMOS image sensors have been extensively used in various applications, such as digital still cameras and digital video cameras.

The CMOS image sensor will now be described with reference to accompanying drawings.

FIG. 1 is an equivalent circuit diagram of a CMOS image sensor including one photodiode and four MOS transistors according to the related art.

The CMOS image sensor includes: a photodiode (PD) for receiving light to generate photo charges; a transfer transistor Tx for transferring photo charges collected at the photodiode PD to a floating diffusion (FD) region; a reset transistor Rx for setting electric potential of the floating diffusion (FD) region to a desired value and for exhausting charges to reset the floating diffusion (FD) region; a drive transistor Dx serving as a source follower buffer amplifier; and a select transistor performing switching for addressing. Also, a load transistor 60 is formed outside of the unit pixel to read an output signal.

FIG. 2 is a sectional view illustrating a unit pixel of the CMOS image sensor according to the related art, in which only important elements related to light focusing are shown.

Referring to FIG. 2, in the CMOS image sensor, a field oxide layer (not shown) for defining an active layer is formed on a semiconductor substrate 11 on which a sensing section and a peripheral drive section are defined. In addition, a plurality of photodiodes PD 12 and transistors 13 are formed in the active area of the semiconductor substrate 11.

A first interlayer dielectric layer 14 is formed on the entire surface of the semiconductor substrate 11 including the sensing section and the peripheral drive section, and a first metal interconnection M1 is formed on the first interlayer dielectric layer 14.

In addition, a second interlayer dielectric layer 15, a second metal interconnection M2, a third interlayer dielectric layer 16, a third metal interconnection M3, a fourth interlayer dielectric layer 17, a fourth metal interconnection M4, and a protective layer are sequentially formed on the first metal interconnection M1.

The second, third and fourth metal interconnections M2, M3 and M4 are formed in the peripheral drive section such that they cannot interfere with light incident to the photodiodes 12.

In addition, red (R), green (G), and blue (B) color filter layers 19 are formed on a planarization layer 18 on the sensing section in order to realize color images. A micro-lens 20 is formed on each color filter layer 19.

In order to obtain a desired curvature of the micro-lens 20, photoresist is coated and patterned such that the photoresist remains on the photodiodes 12. Then, the photoresist is reflowed through a baking process. Micro-lens 20 plays an important role of introducing light to the photodiodes 12.

However, as the semiconductor device becomes highly integrated, the metal interconnections are aligned in different layers, so that the height of the interlayer dielectric layers increases and an interval, or distance, between the micro-lens 20 and the photodiode 12 is enlarged. Thus, it is difficult to properly introduce light to the photodiode PD by using only the micro-lens 20.

Although first and second metal interconnections M1 and M2 are formed in the sensing section, second to fourth interlayer dielectric layers 15, 16 and 17 are formed between the micro-lens 20 and the photodiode 12 receiving the light. Thus, the intensity of light is attenuated when the light reaches the photodiode 12, so that the quality of the image may be degraded.

In addition, since the distance between the micro-lens 20 and the photodiode 12 is enlarged, if the light is incident while deviating from a predetermined incident angle, color interference called “cross-talk” may occur, so that the image quality is degraded.

### BRIEF SUMMARY

An object of the present invention is to provide a method of manufacturing a CMOS image sensor, capable of shortening a distance between a micro-lens and a photodiode to enhance intensity of light incident into the photodiode and simplifying the manufacturing process for the CMOS. Accordingly there is provided a method of manufacturing a CMOS image sensor that can include removing interlayer dielectric layers of a sensing section.

### BRIEF DESCRIPTION OF THE DRAWINGS

FIG. 1 is an equivalent circuit diagram of a unit pixel of a CMOS image sensor including one photodiode and four MOS transistors according to the related art.

FIG. 2 is a sectional view illustrating a unit pixel of a CMOS image sensor according to the related art.

FIG. 3 is a sectional view illustrating a CMOS sensor according to an embodiment of the present invention.

FIGS. 4A to 4F are sectional views illustrating the procedure for manufacturing a CMOS image sensor according to an embodiment of the present invention.

FIGS. 5A to 5E are sectional views illustrating the procedure for manufacturing a CMOS image sensor according to another embodiment of the present invention.

### DETAILED DESCRIPTION OF THE INVENTION

Hereinafter, preferred embodiments of the CMOS image sensor and the method of manufacturing the same will be described with reference to accompanying drawings.

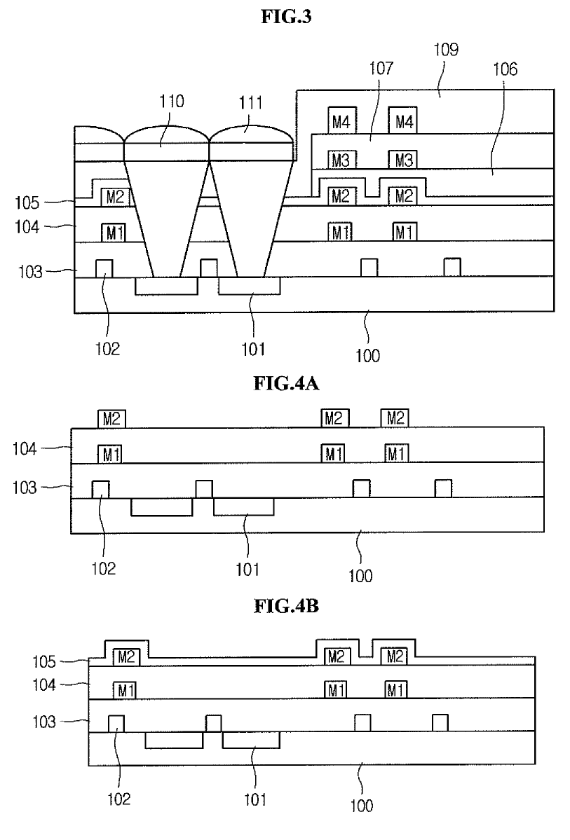

FIG. 3 is a sectional view illustrating a CMOS sensor according to a first embodiment of the present invention.

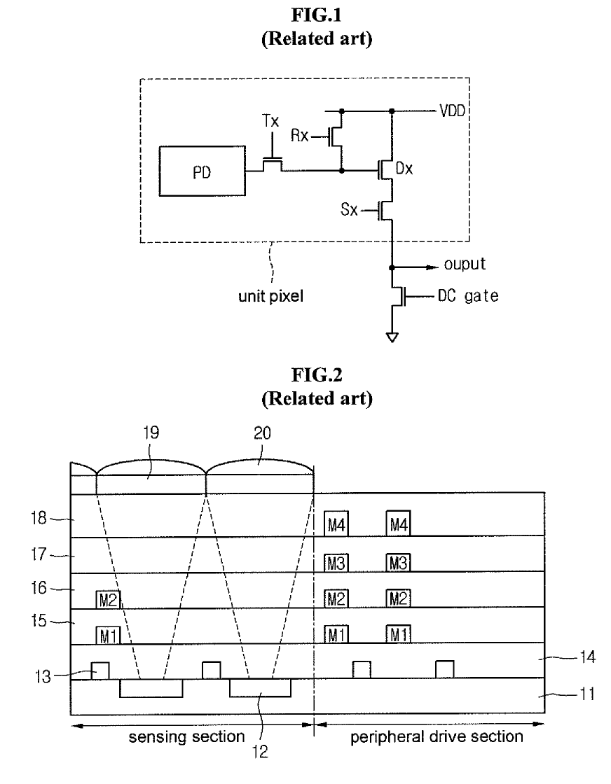

Referring to FIG. 1, the CMOS image sensor can include: a plurality of photodiodes 101 and transistors 102 formed on a semiconductor substrate 100 on which a sensing section and a peripheral drive section are defined; a first interlayer dielectric layer 103 formed on the entire surface of the semiconductor substrate 100 including the photodiodes 101 and transistors 102; a first metal interconnection M1 formed on the sensing section and the peripheral drive section of the first interlayer dielectric layer 103; a second interlayer dielectric layer 104 formed on the entire surface of the semiconductor substrate 100 including the first metal interconnection M1; a second metal interconnection M2 formed on the sensing section and the peripheral drive section of the second interlayer dielectric layer 104; a nitride layer 105 formed on the entire surface of the semiconductor substrate 100 including the second metal interconnection M2; a third interlayer dielectric layer 106 formed on the peripheral drive section of the nitride layer 105; a third metal interconnection M3 formed on the third interlayer dielectric layer 106; a fourth interlayer dielectric layer 107 formed on the peripheral drive section of the semiconductor substrate 100 including the third metal interconnection M3; a fourth metal interconnection formed on the fourth interlayer dielectric layer 107; a planarization layer 109 formed on the entire surface of the semiconductor substrate 100 including the fourth metal interconnection M4; and color filter layers 110 and micro-lenses 111 sequentially formed on the sensing section of the planarization layer 109.

That is, in the CMOS image sensor according to the first embodiment of the present invention, the first and second interlayer dielectric layers 103 and 104 are formed on the sensing section and the first to fourth interlayer dielectric layers 103 to 107 are formed on the peripheral drive section, thereby shortening the distance between the micro-lens 111 and the photodiode 101.

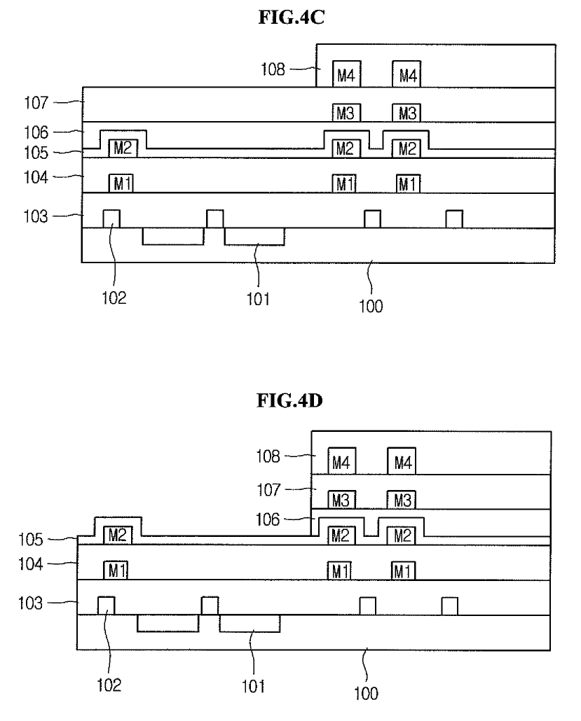

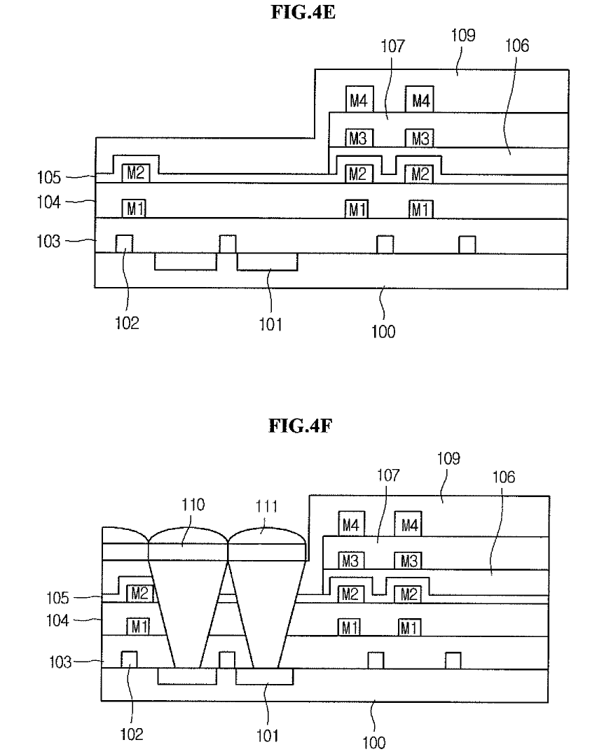

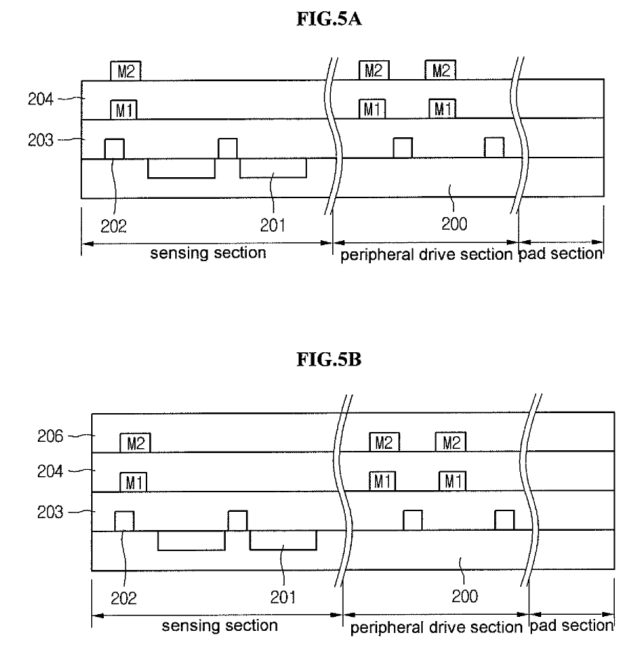

FIGS. 4A to 4F are sectional views illustrating a procedure for manufacturing a CMOS image sensor according to a first embodiment of the present invention.

Referring to FIG. 4A, a field oxide layer (not shown) for defining an active layer can be formed on the semiconductor substrate 100 on which the sensing section and the peripheral drive section are defined. A plurality of photodiodes 101 and transistors 102 can be formed in the active area of the semiconductor substrate 100. The plurality of photodiodes 101 and some of the plurality of transistors are formed on the sensing section, and the rest of the plurality of transistors 102 are formed on the peripheral drive section.

Then, a first interlayer dielectric layer 103 can be formed on the entire surface of the semiconductor substrate 100 including the photodiodes 101 and transistors 102. After that, a first metal layer is deposited and selectively patterned on the first interlayer dielectric layer 103, thereby forming the first metal interconnection M1 in the sensing section and the peripheral drive section.

Next, a second interlayer dielectric layer 104 can be formed on the entire surface of the semiconductor substrate 100 including the first metal interconnection M1. After that, a second metal layer can be deposited and selectively patterned on the second interlayer dielectric layer 104, thereby forming the second metal interconnection M2 in the sensing section and the peripheral drive section.

Then, referring to FIG. 4B, an etch-stop nitride layer 105 can be formed on the entire surface of the semiconductor substrate 100 including the second metal interconnection M2.

After that, referring to FIG. 4C, a third interlayer dielectric layer 106 can be formed on the nitride layer 105. Then, a third metal layer can be deposited and selectively patterned on the third interlayer dielectric layer 106, thereby forming the third metal interconnection M3 in the peripheral drive section.

Then, a fourth interlayer dielectric layer 107 can be formed on the entire surface of the semiconductor substrate 100 including the third metal interconnection M3. A fourth metal layer can then be deposited and selectively patterned on the fourth interlayer dielectric layer 107, thereby forming the fourth metal interconnection M4 in the peripheral drive section.

Subsequently, a photoresist 108 can be coated on the entire surface of the semiconductor substrate 100 including the fourth metal interconnection M4, and then the photoresist 108 can be patterned by an exposure and development process such that the photoresist 108 remains only on the peripheral drive section.

Then, referring to FIG. 4D, the fourth interlayer dielectric layer 107 and the third interlayer dielectric layer 106 formed on the sensing section of the semiconductor substrate 100 can be selectively removed using the patterned photoresist 108 as a mask.

When selectively removing the fourth interlayer dielectric layer 107 and the third interlayer dielectric layer 106, the nitride layer 105 formed on the second interlayer dielectric layer 104 may serve as an etch stop layer.

In an embodiment, the third and fourth interlayer dielectric layers 106 and 107 can be etched by a wet etching process, a dry etching process or a wet-dry etching process.

Referring to FIG. 4E, the photoresist 108 can be removed and a planarization layer 109 can be formed on the entire surface of the semiconductor substrate 100. In one embodiment, the planarization layer can be a nitride layer.

Referring to FIG. 4F, a dyeable resist can be coated on the planarization layer 109, and then the dyeable resist can be patterned by exposure and development processes to form color filter layers 110 on the sensing section. The color filter layers 110 can be aligned at a predetermined interval to filter light according to the wavelength thereof.

Then, a material layer for forming a micro-lens can be coated on the entire surface of the semiconductor substrate 100 including the color filter layers 110, and the material layer can be patterned by exposure and development processes to form a micro-lens pattern on the color filter layers 110.

The material layer for forming the micro-lens can be a resist or an oxide layer, such as a TEOS layer.

In a further embodiment, a second planarization layer (not shown) can be formed on the color filter layer 110 before forming the material layer for forming the micro-lens.

Referring again to FIG. 4F, the micro-lens pattern can be reflowed at a temperature of about 150° C. to 200° C. to form the micro-lens 111. Here, a hot plate or a furnace can be employed during the reflow process. The curvature of the micro-lens 111 may vary depending on the thermal compression scheme, and the focusing efficiency of the micro-lens 111 is changed according to the curvature of the micro-lens 111.

Subsequently, ultraviolet rays can be irradiated onto the micro-lens 111 to cure the micro-lens 11. Since the micro-lens 111 is cured by means of the ultraviolet rays, the micro-lens 111 may have an optimum curvature radius.

Accordingly, in the sensing section, the thickness of the interlayer dielectric layer between the micro-lens and the photodiode becomes reduced, so that light loss can be reduced, photo sensitivity can be improved and the cross-talk can be prevented. Thus, the image quality can be enhanced for bright places as well as dark places.

In addition, although not shown in the figures, a contact hole must be formed in a pad section of the fourth metal interconnection M4 formed in the peripheral drive section after the micro-lens 111 has been formed so as to make electric connection to an external drive circuit.

That is, the contact hole is formed to expose the pad section of the fourth metal interconnection M4 by selectively removing the planarization layer 109 formed on the fourth metal interconnection M4.

Therefore, a photolithography process is additionally performed so as to form the pad contact hole.

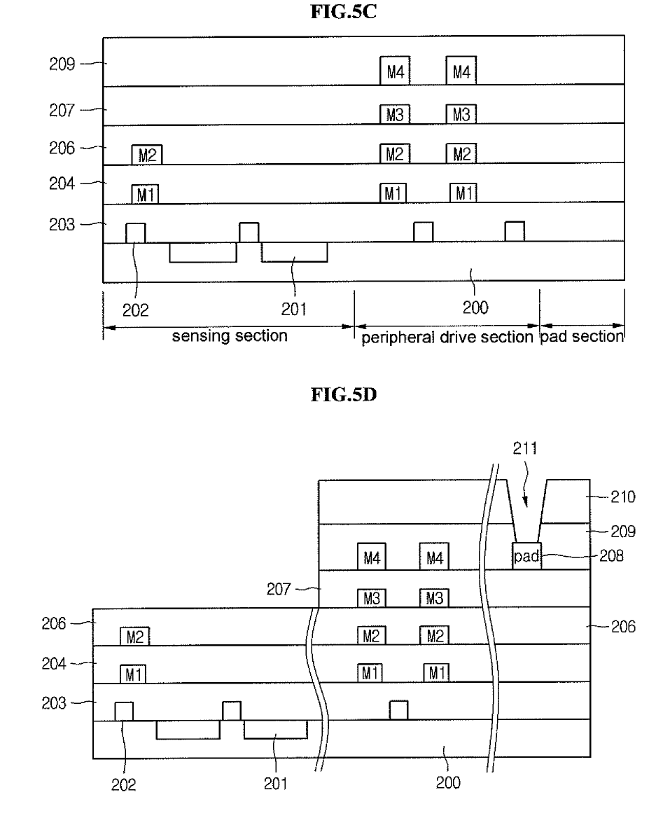

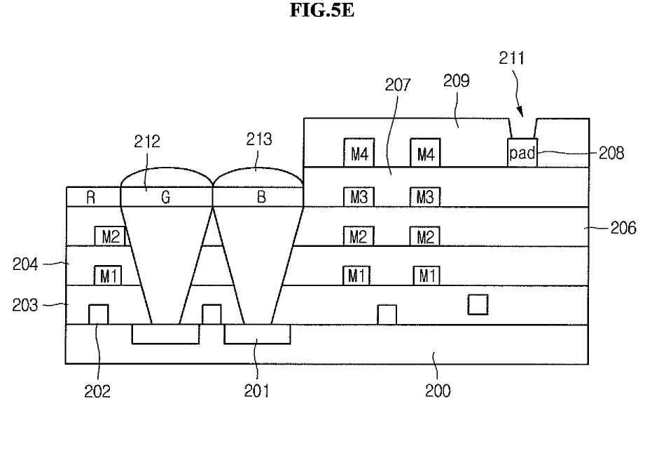

FIGS. 5A to 5E are sectional views illustrating a procedure for manufacturing a CMOS image sensor according to a second embodiment of the present invention.

Referring to FIG. 5A, a field oxide layer (not shown) for defining an active layer can be formed on a semiconductor substrate 200 on which a sensing section and a peripheral drive section are defined. A plurality of photodiodes 201 and transistors 202 can be formed in the active area of the semiconductor substrate 200.

Then, a first interlayer dielectric layer 203 can be formed on the entire surface of the semiconductor substrate 200 including the photodiodes 201 and transistors 202. After that, a first metal layer can be deposited and selectively patterned on the first interlayer dielectric layer 203, thereby forming the first metal interconnection M1 in the sensing section and the peripheral drive section.

Next, a second interlayer dielectric layer 204 can be formed on the entire surface of the semiconductor substrate 200 including the first metal interconnection M1. After that, a second metal layer can be deposited and selectively patterned on the second interlayer dielectric layer 204, thereby forming the second metal interconnection M2 in the sensing section and the peripheral drive section.

Then, referring to FIG. 5B, a third interlayer dielectric layer 206 can be formed on the entire surface of the semiconductor substrate 200 including the second metal interconnection M2.

Next, referring to FIG. 5C, a third metal layer can be deposited and selectively patterned on the third interlayer dielectric layer 206, thereby forming the third metal interconnection M3 in the peripheral drive section.

Then, a fourth interlayer dielectric layer 207 can be formed on the entire surface of the semiconductor substrate 200 including the third metal interconnection M3. In this state, a fourth metal layer can be deposited and selectively patterned on the fourth interlayer dielectric layer 207, thereby forming the fourth metal interconnection M4 in the peripheral drive section. A planarization layer or a protective layer 209 can be formed on the entire substrate including the fourth metal interconnection M4.

In an embodiment, each metal interconnection can be formed by stacking at least one or two of the following: aluminum, copper, molybdenum, titanium and tantalum. In addition, each interlayer dielectric layer can include an oxide-based layer.

Then, referring to FIG. 5D, a photoresist 210 can be coated on the planarization layer or protective layer 209, and then the photoresist 210 can be patterned by an exposure and development process such that the photoresist 210 remains only on the peripheral drive section. In particular the photoresist 210 can remain in the peripheral drive section and the pad section to expose the sensing section and an upper portion of the pad section.

Then the planarization layer, or the protective layer, 209 formed on the sensing section of the semiconductor substrate and the fourth interlayer dielectric layer 207 can be selectively removed through an anisotropic etching process, such as a reactive ion etching (RIE) process, using the patterned photoresist 210 as a mask. At the same time, the planarization layer, or the protective layer, 209 formed on the pad section can be selectively removed, thereby forming a pad contact hole 211.

If the fourth metal interconnection M4 is prepared as a stacked structure of aluminum (Al) and titanium nitride (TiN), and the planarization layer, or the protective layer, 209 and each interlayer dielectric layer include an oxide layer, C₄F₈/Co/N₂/Ar gas can be used during the RIE process. The etching process can be performed while adjusting etching selectivity among a metal layer of the pad section, the planarization layer, or the protective layer, 209, and the fourth interlayer dielectric layer 207. That is, the etching selectivity can be adjusted by controlling the amount of N₂ gas.

In another embodiment, the third interlayer dielectric layer 206 can be used as an etch stop layer by using different materials for the third interlayer dielectric layer 206, the fourth interlayer dielectric layer and the planarization layer, or the protective layer, 209.

That is, if the third interlayer dielectric layer 206 is made from a nitride layer and the fourth interlayer dielectric layer and the planarization layer, or the protective layer, 209 are made from an oxide layer, the third interlayer dielectric layer 206 may serve as an etch stop layer when simultaneously removing the planarization layer, or the protective layer, 209 of the sensing section and the pad section. In this case, the etching selectivity can be improved.

Referring to FIG. 5E, the photoresist 210 can be removed and a dyeable resist can be coated on the entire surface of the semiconductor substrate 200. The dyeable resist can be patterned by exposure and development processes to form color filter layers 212 on the sensing section. The color filter layers 212 can be aligned at a predetermined interval to filter light according to the wavelength thereof.

Next, a material layer for forming a micro-lens can be coated on the entire surface of the semiconductor substrate 200 including the color filter layers 212, and then the material layer can be patterned by exposure and development processes, thereby forming a micro-lens pattern on the color filter layers 212.

The material layer for forming the micro-lens can be a resist or an oxide layer, such as a TEOS layer.

Then, the micro-lens pattern can be reflown at a temperature of about 150° C. to 200° C., thereby forming the micro-lens 213.

Here, a hot plate or a furnace can be employed during the reflow process. At this time, the curvature of the micro-lens 213 may vary depending on the thermal compression scheme, and the focusing efficiency of the micro-lens 213 is changed according to the curvature of the micro-lens 213.

Subsequently, ultraviolet rays can be irradiated onto the micro-lens 213 to cure the micro-lens 213. Since the micro-lens 213 is cured by means of the ultraviolet rays, the micro-lens 213 may have an optimum curvature radius.

Accordingly, in the sensing section, the thickness of the interlayer dielectric layer between the micro-lens and the photodiode becomes reduced, so that light loss can be reduced, photo sensitivity can be improved, and the cross-talk caused by deviation of the light incident angle can be prevented. In addition, since the pad section and the sensing section are simultaneously etched, the process time can be reduced and the manufacturing process can be simplified.

The CMOS image sensor and the method of manufacturing the same according to embodiments of the present invention have the following advantages.

First, the thickness of the interlayer dielectric layer can be reduced between the micro-lens and the photodiode in the sensing section, so that the light loss is reduced, improving photo sensitivity.

Second, the distance between the micro-lens and the photodiode becomes reduced, so that the cross-talk caused by deviation of the light incident angle can be reduced.

Third, since the photo sensitivity is improved and the cross-talk is prevented, the image quality can be enhanced for a bright place as well as a dark place.

Fourth, since the pad section and the sensing section can be simultaneously etched, the process time can be reduced and the manufacturing process can be simplified.

It will be apparent to those skilled in the art that various modifications and variations can be made in the present invention. Thus, it is intended that the present invention covers the modifications and variations thereof within the scope of the appended claims.

I claim:

1. A method of manufacturing a CMOS image sensor, comprising:
forming a plurality of photodiodes and transistors on a semiconductor substrate on which a sensing section and a peripheral drive section are defined;
forming a first interlayer dielectric layer on the semiconductor substrate including the plurality of photodiodes and transistors;
forming a first metal interconnection on the first interlayer dielectric layer in the sensing section and the peripheral drive section;
forming a second interlayer dielectric layer on the semiconductor substrate including the first metal interconnection;
forming a second metal interconnection on the second interlayer dielectric layer in the sensing section and the peripheral drive section;
forming a third interlayer dielectric layer on the semiconductor substrate including the second metal interconnection;
forming a third metal interconnection on the third interlayer dielectric layer in the peripheral drive section;
forming a fourth interlayer dielectric layer on the semiconductor substrate including the third metal interconnection;
forming a fourth metal interconnection on the fourth interlayer dielectric layer in the peripheral drive section and forming a pad on the fourth interlayer dielectric layer in a pad section;
forming a planarization layer on the semiconductor substrate including the fourth metal interconnection and the pad;
selectively removing the planarization layer and the fourth interlayer dielectric layer in the sensing section and simultaneously removing the planarization layer formed on the pad; and
forming color filter layers and micro-lenses on the third interlayer dielectric layer in the sensing section.

2. The method according to claim 1, wherein selectively removing the planarization layer and the fourth interlayer dielectric layer in the sensing section and simultaneously removing the planarization layer formed on the pad comprises performing an RIE (reactive ion etching) process.

3. The method according to claim 1, wherein the first interlayer dielectric layer, the second interlayer dielectric layer, the third interlayer dielectric layer, the fourth interlayer dielectric layer and the planarization layer comprise oxide layers.

4. The method according to claim 1, wherein the first metal interconnection, the second metal interconnection, the third metal interconnection, the fourth metal interconnection and the pad comprise at least one selected from the group consisting of aluminum, copper, molybdenum, titanium and tantalum.

5. The method according to claim 4, wherein the pad comprises a stacked structure of aluminum and titanium, wherein selectively removing the planarization layer and the fourth interlayer dielectric layer in the sensing section and simultaneously removing the planarization layer formed on the pad comprises performing an RIE process using C₄F₈/Co/N₂/Ar gas.

6. The method according to claim 1, wherein the third interlayer dielectric layer comprises a material different than materials forming the fourth interlayer dielectric layer and the planarization layer.

7. The method according to claim 6, wherein the third interlayer dielectric layer comprises a nitride layer, and the fourth interlayer dielectric layer and the planarization layer comprise an oxide layer.

8. A method of manufacturing a CMOS image sensor, comprising:
forming a plurality of photodiodes and transistors on a semiconductor substrate on which a sensing section and a peripheral drive section are defined;
forming a first interlayer dielectric layer on the semiconductor substrate including the plurality of photodiodes and transistors;
forming a first metal interconnection on the first interlayer dielectric layer in the sensing section and the peripheral drive section;
forming a second interlayer dielectric layer on the semiconductor substrate including the first metal interconnection;
forming a second metal interconnection on the second interlayer dielectric layer in the sensing section and the peripheral drive section;
forming a third interlayer dielectric layer on the semiconductor substrate including the second metal interconnection;
forming a third metal interconnection on the third interlayer dielectric layer in the peripheral drive section;
forming a fourth interlayer dielectric layer on the semiconductor substrate including the third metal interconnection;
forming a fourth metal interconnection on the fourth interlayer dielectric layer in the peripheral drive section and forming a pad on the fourth interlayer dielectric layer in a pad section;
forming a protective layer on the semiconductor substrate including the fourth metal interconnection and the pad;
selectively removing the protective layer and the fourth interlayer dielectric layer of the sensing section and simultaneously removing the protective layer formed on the pad; and
forming color filter layers and micro-lenses on the third interlayer dielectric layer in the sensing section.

9. A method of manufacturing a CMOS image sensor, comprising:
forming a plurality of photodiodes and transistors on a semiconductor substrate on which a sensing section and a peripheral drive section are defined;
forming a first interlayer dielectric layer on the semiconductor substrate including the plurality of photodiodes and transistors;
forming a first metal interconnection on the first interlayer dielectric layer in the sensing section and the peripheral drive section;
forming a second interlayer dielectric layer on the semiconductor substrate including the first metal interconnection;
forming a second metal interconnection on the second interlayer dielectric layer in the sensing section and the peripheral drive section;
forming a third interlayer dielectric layer on the semiconductor substrate including the second metal interconnection;
forming a third metal interconnection on the third interlayer dielectric layer in the peripheral drive section;
forming a fourth interlayer dielectric layer on the semiconductor substrate including the third metal interconnection;
forming a fourth metal interconnection and a pad on the fourth interlayer dielectric layer in the peripheral drive section;
forming a protective layer on the semiconductor substrate including the fourth metal interconnection and the pad;
selectively removing the protective layer and the fourth interlayer dielectric layer in the sensing section;
forming color filter layers and micro-lenses on the third interlayer dielectric layer in the sensing section; and
selectively etching the protective layer of the peripheral drive section to form a contact hole connected to the pad.
